(19) United States
(12) Patent Application Publication
(10) Pub. No.: US 2023/0156923 A1
(43) Pub. Date: May 18, 2023

(54) PLATED MOLDED ARTICLE AND METHOD FOR MANUFACTURING PLATED MOLDED ARTICLE

(71) Applicant: SANKEI GIKEN KOGYO CO., LTD., Tokyo (JP)

(72) Inventors: Toshiyuki Kitamura, Tokyo (JP); Daiji Hasegawa, Tokyo (JP); Toshio Okabe, Tokyo (JP)

(73) Assignee: SANKEI GIKEN KOGYO CO., LTD., Tokyo (JP)

(21) Appl. No.: 17/916,344

(22) PCT Filed: Feb. 16, 2021
(86) PCT No.: PCT/JP2021/005783

§ 371 Date: Sep. 30, 2022

(30) Foreign Application Priority Data
Apr. 2, 2020 (JP) 2020-066333

(51) Int. Cl. H05K 3/00; H05K 3/38; H05K 1/02

(52) U.S. Cl. CPC H05K 3/0035; H05K 3/38; H05K 1/02; H05K 2203/0361

(57) ABSTRACT

A plated molded article 1 is characterized in that a partial region R in a surface 21 of a base material 2 is provided with a plurality of non-penetrating holes 4 of substantially corresponding shapes and substantially corresponding sizes that are formed in a scattered pattern in such a manner as to be separated from each other at a substantially averaged hole density, and a plated part 3 is formed while filling the non-penetrating holes 4 and is provided continuously over the partial region R in such a manner as to extend across the non-penetrating holes 4. It is possible to obtain a plated molded article capable of forming a required plated part in a short time on a surface of a base material and capable of improving smoothness of an outer surface of the plated part and adhesion property of the plated part.

### TECHNICAL FIELD

The present invention relates to a plated molded article and a method for manufacturing a plated molded article with a plated part formed on a surface of a base material.

### BACKGROUND ART

A molded interconnect device (MID) is conventionally known as a plated molded article with a plated part formed on a surface of a base material. Such a molded interconnect device is generally manufactured by forming a groove having a width substantially corresponding to the width of a conductor of a circuit by laser processing from a surface of a resin base material, performing electroless plating in such a manner as to bury the groove, and forming the conductor at a plated part substantially corresponding to the groove width (see FIG. 1, FIG. 2, and paragraphs [0050] to [0056] in Patent Literature 1).

### PRIOR ART LITERATURE

### Patent Literature

Patent Literature 1: Japanese Patent Application Publication No. 2011-29494

### SUMMARY OF INVENTION

### Problem to be Solved by Invention

As shown in FIG. 8, in order to form a groove 102 of a predetermined width corresponding to a circuit groove at a surface 101 of a resin base material 100 and to form a plated part 103 substantially corresponding to the groove width in such a manner as to bury the groove 102, forming an electroless plated part 103a by performing electroless plating and then forming an electroplated part 103b by performing electroplating results in formation of the electroplated part 103b only by an amount in an hour between lines of alternate long and two short dashes shown in FIG. 7(b), for example. This causes a problem that burying the groove 102 of a large volume and forming the required plated part 103 on the surface 101 of the resin base material 100 takes a considerably long time.

Additionally, forming the plated part 103 at the groove 102 of a width substantially corresponding to the width of the plated part 103 also causes a problem that smoothness of an outer surface of the plated part 103 to be formed is damaged due to unevenness of the groove having a large width and a large height difference. Furthermore, as the plated part 103 described above is only in contact with a bottom surface and a side surface of the groove 102 for its adhesion to the groove 102, an issue of poor adhesion property also occurs.

The present invention is suggested in view of the above-described problems, and is intended to provide a plated molded article and a method for manufacturing a plated molded article capable of forming a required plated part in a short time on a surface of a base material and capable of improving smoothness of an outer surface of the plated part and adhesion property of the plated part.

### Means of Solving Problem

A plated molded article of the present invention is characterized in that a partial region in a surface of a base material is provided with a plurality of non-penetrating holes of substantially corresponding shapes and substantially corresponding sizes that are formed in a scattered pattern in such a manner as to be separated from each other at a substantially averaged hole density, and a plated part is formed while filling the non-penetrating holes and is provided continuously over the partial region in such a manner as to extend across the non-penetrating holes.

By doing so, the need of forming the plated part by filling of a groove of a large volume is eliminated. Thus, the required plated part can be formed in a short time on the surface of the base material. Furthermore, compared to forming a large groove, forming the non-penetrating holes can reduce an amount of partial removal from the base material. This further makes it possible to shorten processing time required for the partial removal from the base material. In this way, it becomes possible to encourage shortening of time for manufacturing the plated molded article and increased efficiency of manufacturing steps. Moreover, the occurrence of a large height difference of an outer surface of the plated part is prevented that is to be caused by unevenness of a groove having a large width and a large height difference, allowing smoothness of the outer surface of the plated part to be improved. Moreover, the improved smoothness of the outer surface of the plated part makes it possible to minimize or eliminate a processing step of smoothing the outer surface of the plated part to an intended level. Additionally, anchor effect is achieved at portions of the plated part filling the non-penetrating holes, allowing improvement of adhesion property of the plated part.

The plated molded article of the present invention is characterized in that the non-penetrating holes and portions of the plated part filling the non-penetrating holes each have a substantially tapered shape with a diameter decreasing gradually toward the back of the non-penetrating hole.

By doing so, the anchor effect achieved at the portions of the plated part filling the non-penetrating holes is improved further, so that the plated part can be provided with more improved adhesion property. Furthermore, forming the non-penetrating hole into a substantially tapered shape minimizes a part to be removed from the base material by laser processing, for example, making it possible to shorten time of processing the base material.

The plated molded article of the present invention is characterized in that the non-penetrating holes have a hole area from 3.1×10² to 1256×10² μm² and the non-penetrating holes have a hole volume of 0.9×10³ to 31316×10³ μm³.

This allows formation of the plated part by connecting plated portions filling the respective non-penetrating holes in a considerably short time such as one hour, for example, and achieves improvement of smoothness and adhesion property of the plated part more reliably.

The plated molded article of the present invention is characterized in that the non-penetrating holes have a hole area from 3.1×10² to 1256×10² μm² and a mutual spacing ratio between the non-penetrating holes is from 0.16 to 1.30.

By doing so, overlap between the non-penetrating holes is prevented reliably to ensure favorable deposition property of plating, and the plated portions filling the respective non-penetrating holes can be connected reliably to provide the plated part continuously.

The plated molded article of the present invention is characterized in that the non-penetrating holes are arranged in a staggered pattern or in rows and in columns in a direction in which the partial region extends.

By doing so, a probability that the plated part will be thinned locally is minimized. This makes it possible to provide the plated part continuously by connecting the plated portions filling the respective non-penetrating holes reliably while improving smoothness of the outer surface of the plated part to a greater extent.

The plated molded article of the present invention is characterized in that the base material is an insulating resin base material and the partial region in the surface of the base material is a region substantially corresponding to a conductor, the non-penetrating holes are formed at respective positions differing from each other in a direction of the width of the conductor and are formed in a direction in which the conductor extends, and the conductor is formed using the plated part to form a molded interconnect device.

By doing so, the need of forming the plated part by filling of a circuit groove of a large volume is eliminated. Thus, the required plated part can be formed in a short time on the surface of the base material. In this way, it becomes possible to encourage shortening of time for manufacturing the molded interconnect device and increased efficiency of manufacturing steps. Moreover, the occurrence of a large height difference of the outer surface of the plated part is prevented that is to be caused by unevenness of a circuit groove having a large width and a large height difference, allowing smoothness of the outer surface of the plated part to be improved and allowing equipment to be mounted reliably on the plated part of the molded interconnect device. Additionally, anchor effect is achieved at portions of the plated part filling the non-penetrating holes, allowing improvement of adhesion property of the plated part of the molded interconnect device.

A method for manufacturing a plated molded article of the present invention is a method for manufacturing the plated molded article of the present invention, comprising: a first step of boring holes in a partial region in a surface of an insulating base material by laser processing to form a plurality of non-penetrating holes in such a manner that the non-penetrating holes are separated from each other at a substantially averaged hole density; and a second step of performing electroless plating in the partial region in the base material provided with the non-penetrating holes to provide a plated part continuously over the partial region in such a manner that the plated part fills the non-penetrating holes and extends across the non-penetrating holes.

If a plated part is to be formed by using electroless plating by burying a groove such as an existing circuit groove, a considerably long time is required for an electroless plating processing step as a deposition speed is low in electroless plating. In response to this, in the above-described configuration, the plated part is formed in such a manner as to extend continuously by filling the non-penetrating holes with plated portions by electroless plating. Thus, time required for the electroless plating processing step can be shortened significantly. Furthermore, performing only electroless plating without performing electroplating suppresses unbalance of a thickness, making it possible to improve smoothness of the outer surface of the plated part to a greater extent. Additionally, performing only electroless plating without performing electroplating makes wiring for electric conduction and a facility for electroplating unnecessary and can minimize the occurrence of a situation where a region for the plated part covering the partial region becomes larger than necessary.

A method for manufacturing a plated molded article of the present invention is a method for manufacturing the plated molded article of the present invention, comprising: a first step of boring holes in a partial region in a surface of an insulating base material by laser processing to form a plurality of non-penetrating holes in such a manner that the non-penetrating holes are separated from each other at a substantially averaged hole density; and a second step of performing electroless plating and electroplating sequentially in the partial region in the base material provided with the non-penetrating holes to provide a plated part continuously over the partial region in such a manner that the plated part fills the non-penetrating holes and extends across the non-penetrating holes.

If a plated part is to be formed by using electroless plating and electroplating sequentially by burying a groove such as an existing circuit groove, unevenness of the groove having a large height difference causes a large current difference between a high-current part and a low-current part during electroplating to increase a thickness difference of the plated part between the high-current part and the low-current part. In response to this, in the above-described configuration, the plated part is formed in such a manner as to extend continuously by filling the non-penetrating holes with plated portions by performing electroless plating and electroplating sequentially. Thus, the current difference between the high-current part and the low-current part during electroplating is minimized and the difference in plating thickness between the high-current part and the low-current part is minimized. This improves uniform electrodeposition property while suppressing fluctuations, making it possible to form the plated part with high uniformity.

A method for manufacturing a plated molded article of the present invention is a method for manufacturing the plated molded article of the present invention, comprising: a first step of boring holes in a partial region in a surface of a conductive base material by laser processing to form a plurality of non-penetrating holes in such a manner that the non-penetrating holes are separated from each other at a substantially averaged hole density; and a second step of performing electroplating in the partial region in the base material provided with the non-penetrating holes to provide a plated part continuously over the partial region in such a manner that the plated part fills the non-penetrating holes and extends across the non-penetrating holes.

If electroplating is used for forming the plated part by burying a groove of a size comparable to that of an existing circuit groove, unevenness of the groove having a large height difference causes a large current difference between a high-current part and a low-current part to increase a thickness difference of the plated part between the high-current part and the low-current part. In response to this, in the above-described configuration, by forming the plated part continuously by filling the non-penetrating holes with plated portions through electroplating, the current difference between the high-current part and the low-current part is minimized and the difference in plating thickness between the high-current part and the low-current part is minimized. This improves uniform electrodeposition property while suppressing fluctuations, making it possible to form the plated part with high uniformity.

### Advantageous Effects of Invention

According to the present invention, it is possible to form a required plated part in a short time on a surface of a base material and to improve smoothness of an outer surface of the plated part and adhesion property of the plated part.

### BRIEF DESCRIPTION OF DRAWINGS

FIG. 1 is a perspective view of a plated molded article of a first embodiment according to the present invention.

FIG. 2(a) is a partial perspective view of a plated part forming region in the plated molded article of the first embodiment, FIG. 2(b) is a partial perspective view in a state where a plated part is detached from the plated part forming region in FIG. 2(a), and FIG. 2(c) is a partial perspective view in a state where a plated part is detached from a plated part forming region of a modification.

FIG. 3 is a partial longitudinal sectional explanatory view of the plated part forming region in the plated molded article of the first embodiment.

FIGS. 4(a) to 4(f) are explanatory process views explaining steps of forming the plated part of the plated molded article of the first embodiment by performing electroless plating and electroplating sequentially.

FIGS. 5(a) to 5(f) are explanatory process views explaining steps of forming a plated part of a plated molded article of a modification of the first embodiment by performing electroless plating.

FIG. 6 is a partial longitudinal sectional explanatory view of a plated part forming region in a plated molded article of a second embodiment.

FIGS. 7(a) to 7(f) are explanatory process views explaining steps of forming a plated part of the plated molded article having a conductive base material of the second embodiment by performing electroplating.

FIG. 8(a) is a partial perspective view of a resin base material provided with a circuit groove at a plated molded article of a comparative example, and FIG. 8(b) is a partial longitudinal sectional explanatory view of a plated part forming region in the plated molded article of the comparative example.

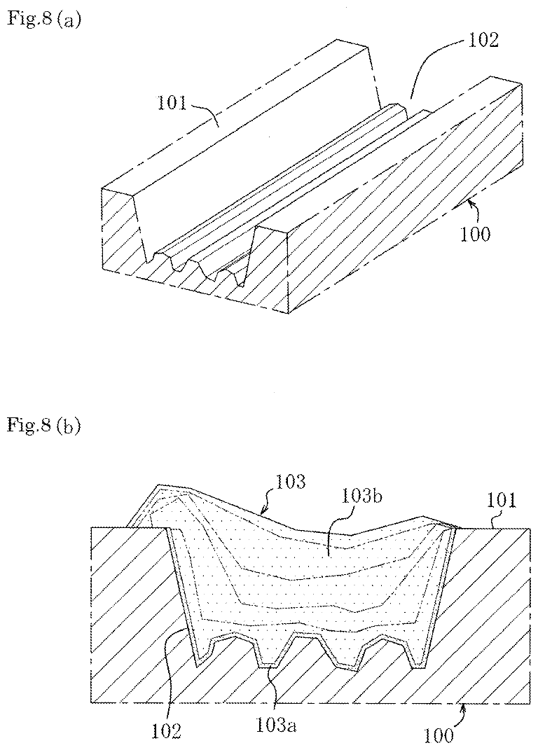

### EMBODIMENTS FOR CARRYING OUT INVENTION

### Plated Molded Article and Method for Manufacturing Plated Molded Article of

### First Embodiment

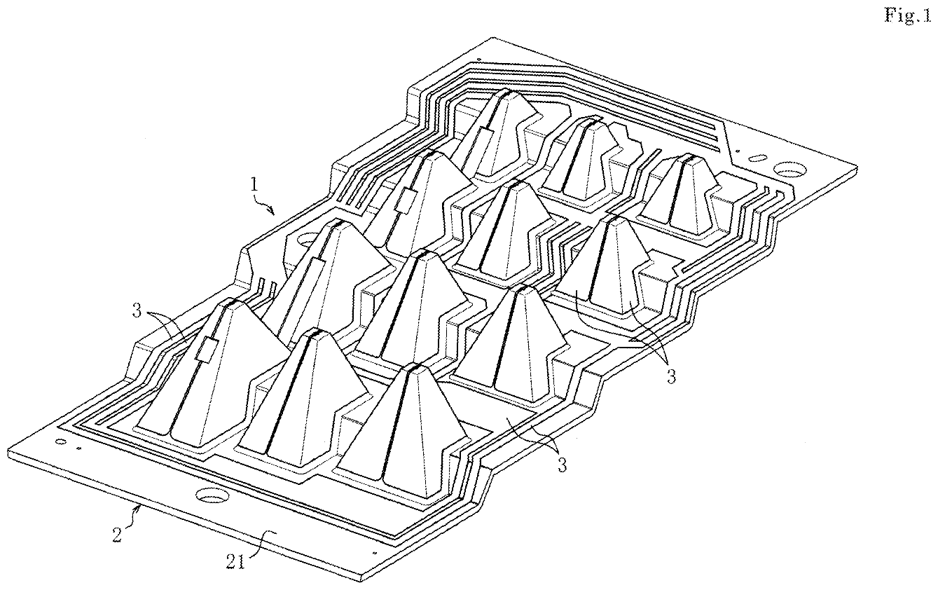

A plated molded article 1 of a first embodiment according to the present invention is a molded interconnect device. As shown in FIGS. 1 to 3, a plated part 3 is formed in such a manner as to cover a partial region R in one surface 21 of a rigid base material 2. In this example, the base material 2 is an insulating resin base material, and the partial region R in the one surface 21 of the base material 2 is a region substantially corresponding to a conductor or a region slightly narrower than the conductor. The conductor is formed at the plated part 3 to form the molded interconnect device.

The partial region R in the one surface 21 of the base material 2 is provided with a plurality of non-penetrating holes 4 of substantially corresponding shapes and substantially corresponding sizes that are formed in a scattered pattern in such a manner as to be separated from each other at a substantially averaged hole density. In other words, the partial region R is a region where the non-penetrating holes 4 of substantially corresponding shapes and substantially corresponding sizes are formed in a scattered pattern in such a manner as to be separated from each other at a substantially averaged hole density.

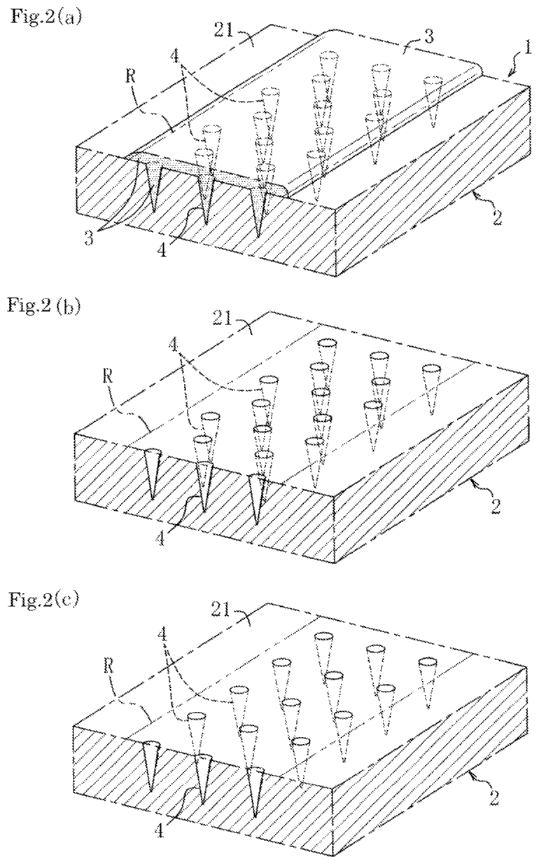

In this example, the non-penetrating holes 4 are arranged in a staggered pattern in a direction in which the partial region R extends, and the non-penetrating holes 4 are formed at respective positions differing from each other in a direction of the width of the conductor and are formed in a direction in which the conductor extends (see FIGS. 2(a) and (b)). As shown in a different example in FIG. 2(c), in a favorable configuration, the non-penetrating holes 4 are arranged in rows and in columns in the direction in which the partial region R extends.

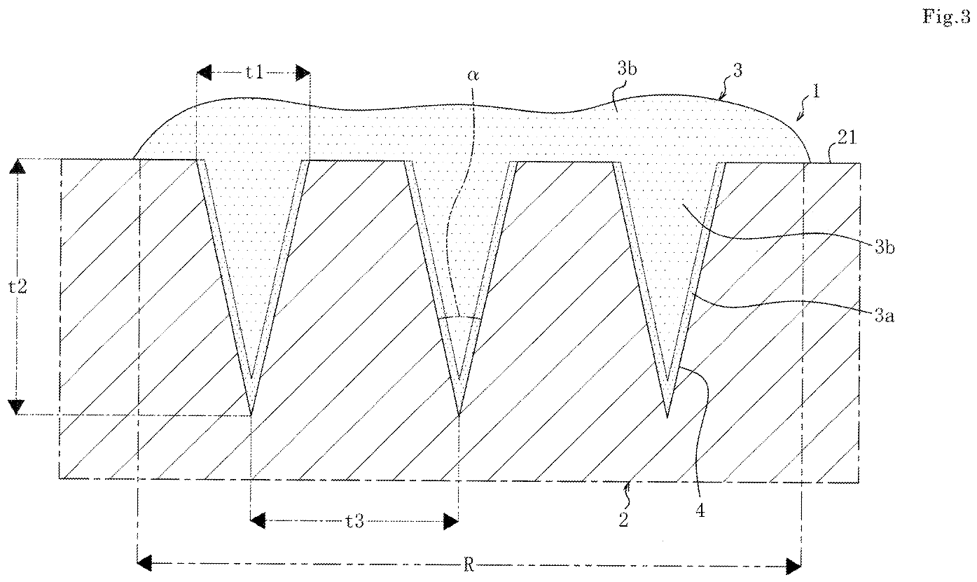

As shown in FIGS. 2 and 3, the plated part 3 of the plated molded article 1 is formed while filling each of the non-penetrating holes 4 of the base material 2. In this example, the non-penetrating hole 4 and a portion of the plated part 3 filling the non-penetrating hole 4 each have a substantially tapered shape with a diameter decreasing gradually toward the back of the non-penetrating hole 4. The plated part 3 is formed on the one surface 21 of the base material 2 continuously over the partial region R in such a manner as to extend across the non-penetrating holes 4. In FIG. 3, t1 is a width defined by a maximum width of the non-penetrating hole 4 at the base material surface 21. If the non-penetrating hole 4 is substantially circular in a plan view, for example, t1 is a hole diameter of the non-penetrating hole 4. Furthermore, t2 is the depth of the non-penetrating hole 4, and t3 is a pitch between the non-penetrating holes 4, 4 and is a distance between the center of the non-penetrating hole 4 and the center of the non-penetrating hole 4.

From the viewpoint of achieving formation of the plated part 3 in a short time, ensuring of smoothness of an outer surface of the plated part 3, and ensuring of adhesion property of the plated part 3 simultaneously, the height or thickness of the plated part 3 from the one surface 21 of the base material 2 is preferably from 0.5 to 1.36 in terms of a thickness ratio (a ratio expressed as:plating thickness/width t1 of non-penetrating hole), the hole area of the non-penetrating hole 4 is preferably from 3.1×10² to 1256×10² μm², more preferably, from 11.3×10² to 88.2×10² μm², the hole volume of the non-penetrating hole 4 is preferably from 0.9×10³ to 31316×10³ μm³, more preferably, from 15×10³ to 341×10³ μm³, and a mutual spacing ratio between the non-penetrating holes 4, 4 is preferably from 0.16 to 1.30, more preferably, from 0.28 to 1.27. Here, the mutual spacing ratio between the non-penetrating holes 4, 4 is defined as: distance between closest positions of non-penetrating holes 4, 4/width t1 of non-penetrating hole 4. From a similar point of view, with the non-penetrating hole 4 formed into a substantially tapered shape or a tapered shape, a taper angle α defined by a line extended from the deepest position of the non-penetrating hole 4 to a periphery of the non-penetrating hole 4 is preferably from 30 to 96 degrees, more preferably, from 30 to 93 degrees. Furthermore, for smoothness of the outer surface of the plated part 3, a height difference of the outer surface of the plated part 3 determined on a base surface in an intermediate region is preferably equal to or less than 25 μm, more preferably, equal to 20 μm, still more preferably, equal to 15 μm, further preferably, 10 μm. Regarding acquisition of a substantially averaged hole density of the non-penetrating holes 4, a difference between a maximum distance and a minimum distance of the shortest separation between the non-penetrating holes 4, 4 is preferably within 50%, and a difference in hole density per 1 mm² in a region where the non-penetrating holes 4 are formed is preferably within 50%.

Moreover, from the viewpoint of forming the plated part 3 by connecting plated portions filling the respective non-penetrating holes 4 in a considerably short time and improving smoothness and adhesion property of the plated part 3 more reliably, the hole area of the non-penetrating hole 4 is preferably from 3.1×10² to 1256×10² μm², more preferably, from 11.3×10² to 88.2×10² μm², and the hole volume of the non-penetrating hole 4 is preferably from 0.9×10³ to 31316×10³ μm³, more preferably, from 15×10³ to 341×10³ μm³. Furthermore, from the viewpoint of preventing overlap between the non-penetrating holes 4, 4 reliably to ensure favorable deposition property of plating and connecting the plated portions filling the respective non-penetrating holes 4 reliably to provide the plated part 3 continuously, the hole area of the non-penetrating hole 4 is preferably from 3.1×10² to 1256×10² μm², more preferably, from 11.3×10² to 88.2×10² μm², and a mutual spacing ratio between the non-penetrating holes 4, 4 is preferably from 0.16 to 1.30, more preferably, from 0.28 to 1.27.

The plated part 3 of the example in FIG. 3 is composed of an electroless plated part 3a and an electroplated part 3b. The electroless plated part 3a is formed as a layer on an inner peripheral surface of the non-penetrating hole 4 and is fixedly attached to the inner peripheral surface of the non-penetrating hole 4. The electroplated part 3b fills the interior of the electroless plated part 3a of each of the non-penetrating holes 4 and is provided continuously over the partial region R in the one surface 21 of the base material 2 in such a manner as to extend across the non-penetrating holes 4, 4.

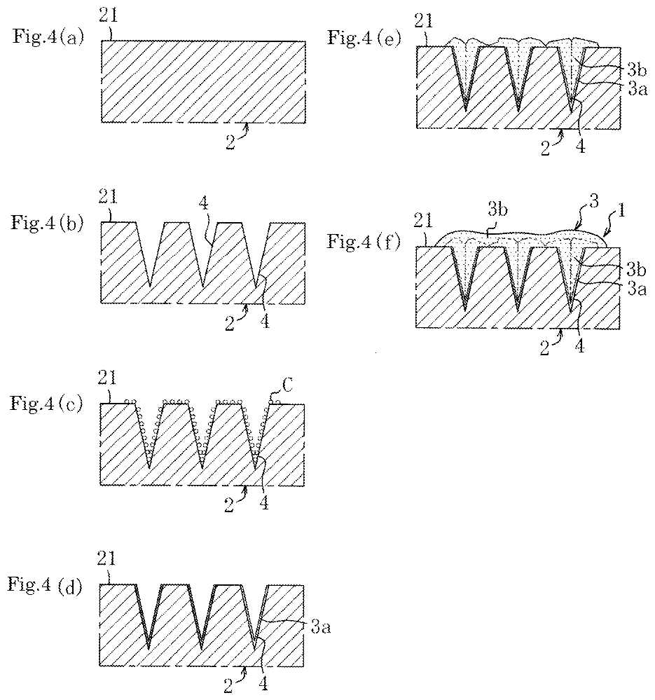

As shown in FIG. 4, for forming the plated part 3 of the plated molded article 1 of the first embodiment, holes are bored by laser processing in the partial region R in the one surface 21 of the base material 2 as an insulating resin base material to form the non-penetrating holes 4 in such a manner that the non-penetrating holes 4 are separated from each other at a substantially averaged hole density (see FIGS. 4(a) and (b)). A laser used in this laser processing is an appropriately available laser such as a carbon dioxide laser, an ultraviolet laser, a YAG laser, a fiber laser, a semiconductor laser, or a hybrid laser of a fiber laser and a semiconductor laser, for example.

Then, electroless plating and electroplating are performed sequentially in the partial region R in the base material 2 provided with the non-penetrating holes 4, thereby forming the plated part 3 composed of the electroless plated part 3a and the electroplated part 3b. The plated part 3 is provided continuously over the partial region R in such a manner as to fill the non-penetrating holes 4 and to extend across the non-penetrating holes 4 (see FIGS. 4(c) to (f).

In a step of performing electroless plating in the partial region R in the base material 2 provided with the non-penetrating holes 4, the base material 2 with the non-penetrating holes 4 is degreased, masking is provided in a region where formation of the plated part 3 is unnecessary, and catalysts C such as palladium are deposited and provided in a region where plating is required through immersion into a mixed catalyst solution of tin and palladium (see FIG. 4(c)), for example. Then, the base material 2 is immersed into an electroless plating bath containing a salt of a metal (including an alloy thereof) deposited on the surface 21 of the base material 2, a reducing agent, etc., thereby forming the electroless plated part 3a on the inner peripheral surface of the non-penetrating hole 4 and on its vicinity (see FIG. 4(d)). For example, the electroless plated part 3a is favorably made of copper or a copper alloy, nickel or a nickel alloy, palladium or a palladium alloy, tin or a tin alloy, silver or a silver alloy, gold or a gold alloy, or cobalt or a cobalt alloy. An electroless plating bath responsive to such a material is used in response to need to perform electroless plating process.

Next, electroplating is performed on the electroless plated part 3a to form the electroplated part 3b in such a manner as to stack the electroplated part 3b on the electroless plated part 3a. While the electroplated part 3b is preferably made of metal of the same type as that of the electroless plated part 3a, it may be made of a different type of metal. In response to deposition and growth, the electroplated part 3b fills the interior of the electroless plated part 3a at each of the non-penetrating holes 4, and at the same time, is provided continuously over the partial region R in the one surface 21 of the base material 2 in such a manner as to extend across the non-penetrating holes 4, 4 (see FIGS. 4(e) and (f)). The electroplated part 3b is deposited and grown with time while passing a state indicated by lines of alternate long and two short dashes in the drawing.

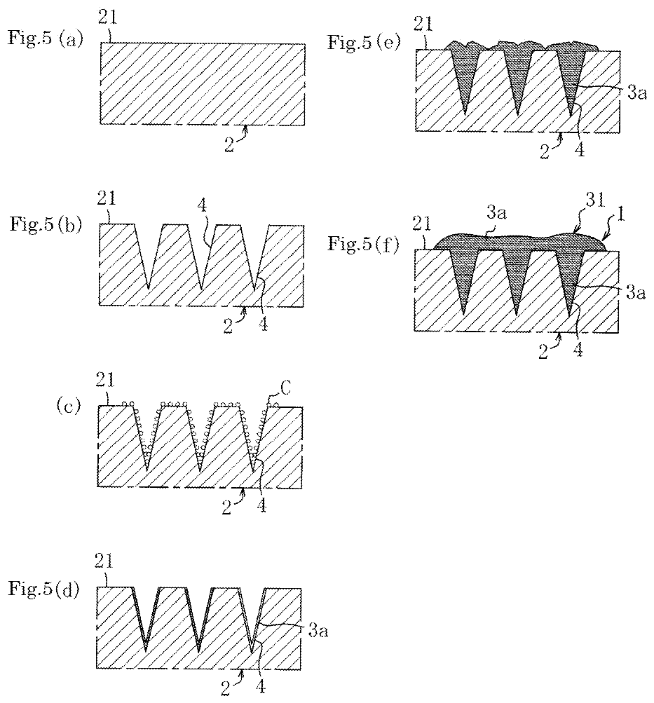

In the plated molded article 1 of the first embodiment, as an alternative to the configuration of forming the plated part 3 composed of the electroless plated part 3a and the electroplated part 3b, a configuration of a modification shown in FIG. 5(f) is also applicable in which a plated part 31 composed only of the electroless plated part 3a is formed. The electroless plated part 3a of the plated part 31 in the plated molded article 1 of the modification is formed as a layer on an inner peripheral surface of the non-penetrating hole 4 and is fixedly attached to the inner peripheral surface of the non-penetrating hole 4, fills each of the non-penetrating holes 4, and is provided continuously over the partial region R in the one surface 21 of the base material 2 in such a manner as to extend across the non-penetrating holes 4, 4. The configuration in other respects of the plated molded article 1 of the modification of the first embodiment is the same as that of the plated molded article 1 of the first embodiment.

Like in the first embodiment, for forming the plated part 31 of the plated molded article 1 of the modification of the first embodiment, holes are bored by laser processing in the partial region R in the one surface 21 of the base material 2 as an insulating resin base material to form the non-penetrating holes 4 in such a manner that the non-penetrating holes 4 are separated from each other at a substantially averaged hole density (see FIGS. 5(a) and (b)). Then, electroless plating is performed in the partial region R in the base material 2 provided with the non-penetrating holes 4, thereby forming the plated part 3 composed of the electroless plated part 3a. The plated part 3 is provided continuously over the partial region R in such a manner as to fill the non-penetrating holes 4 and to extend across the non-penetrating holes 4 (see FIGS. 5(c) to (f)).

Like in the electroless plating process of the first embodiment described above, in a step of performing electroless plating in the partial region R in the base material 2 of the modification provided with the non-penetrating holes 4, the base material 2 with the non-penetrating holes 4 is degreased, masking is provided in a region where formation of the plated part 3 is unnecessary, and catalysts C such as palladium are deposited and provided in a region where plating is required (see FIG. 5(c)), for example. Then, the electroless plated part 3a is formed on the inner peripheral surface of the non-penetrating hole 4 and on its vicinity through immersion into an electroless plating bath (see FIG. 4(d)). For example, the electroless plated part 3a is favorably made of copper or a copper alloy, nickel or a nickel alloy, palladium or a palladium alloy, tin or a tin alloy, silver or a silver alloy, gold or a gold alloy, or cobalt or a cobalt alloy. An electroless plating bath responsive to such a material is used in response to need to perform electroless plating process.

The process of forming the electroless plated part 3a is continued. As a result, in response to deposition and growth, the electroplated part 3a fills the interior of each of the non-penetrating holes 4, and at the same time, is provided continuously over the partial region R in the one surface 21 of the base material 2 in such a manner as to extend across the non-penetrating holes 4, 4 (see FIGS. 5(e) and (f).

According to the plated molded article of the first embodiment or its modification, plating is grown from the bottom and the side surface of the non-penetrating hole 4 and from the surface of the base material to grow the plating in a short time while filling the non-penetrating hole 4 of a small volume with the plating. Specifically, the need of forming a plated part by filling of a groove of a large volume is eliminated. Thus, while five hours or 10 hours have been required for formation of a plated part, it becomes possible to form the plated part in one hour, for example. In this way, the required plated part 3 or 31 can be formed in a short time on the surface 21 of the base material 2. Furthermore, compared to forming a large groove, forming the non-penetrating holes 4 can reduce an amount of partial removal from the base material 2. This further makes it possible to shorten processing time required for the partial removal from the base material 2. In this way, it becomes possible to encourage shortening of time for manufacturing the plated molded article 1 and increased efficiency of manufacturing steps. Moreover, the occurrence of a large height difference of the outer surface of the plated part is prevented that is to be caused by unevenness of a groove having a large width and a large height difference, allowing smoothness of the outer surface of the plated part 3 or 31 to be improved. Moreover, the improved smoothness of the outer surface of the plated part 3 or 31 makes it possible to minimize or eliminate a processing step of smoothing the outer surface of the plated part 3 to an intended level. Additionally, anchor effect is achieved at portions of the plated part 3 or 31 filling the non-penetrating holes 4, allowing improvement of adhesion property of the plated part 3 or 31.

In particular, in a configuration of a molded interconnect device formed by using an insulating resin base material as the base material 2, defining the partial region R in the surface 21 of the base material 2 as a region substantially corresponding to a conductor, forming the non-penetrating holes 4 at respective positions differing from each other in a direction of the width of the conductor and in a direction in which the conductor extends, and forming the conductor using the plated part 3 or 31, the need of forming a plated part by filling of a circuit groove of a large volume is eliminated. Thus, the required plated part 3 or 31 can be formed in a short time on the surface 21 of the base material 2. In this way, it becomes possible to encourage shortening of time for manufacturing the molded interconnect device and increased efficiency of manufacturing steps. Moreover, the occurrence of a large height difference of the outer surface of the plated part is prevented that is to be caused by unevenness of a circuit groove having a large width and a large height difference, allowing smoothness of the outer surface of the plated part 3 or 31 to be improved and allowing equipment to be mounted reliably on the plated part 3 or 31 of the molded interconnect device. Additionally, anchor effect is achieved at portions of the plated part 3 or 31 filling the non-penetrating holes 4, allowing improvement of adhesion property of the plated part 3 or 31 of the molded interconnect device.

By forming each of the non-penetrating hole 4 and a portion of the plated part 3 or 31 filling the non-penetrating hole 4 into a substantially tapered shape with a diameter decreasing gradually toward the back of the non-penetrating hole 4, the anchor effect achieved at the portions of the plated part 3 or 31 filling the non-penetrating holes 4 is improved further, so that the plated part 3 or 31 can be provided with more improved adhesion property. Furthermore, forming the non-penetrating hole 4 into a substantially tapered shape minimizes a part to be removed from the base material 2 by laser processing, for example, making it possible to shorten time of processing the base material 2.

Arranging the non-penetrating holes 4 in a staggered pattern or in rows and in columns in the direction in which the partial region R extends minimizes a probability that the plated part 3 or 31 will be thinned locally. This makes it possible to provide the plated part 3 or 31 continuously by connecting plated portions filling the respective non-penetrating holes 4 reliably while improving smoothness of the outer surface of the plated part 3 or 31 to a greater extent.

For formation of the plated part 3 by performing electroless plating and electroplating sequentially, if a plated part is to be formed by using electroless plating and electroplating sequentially by burying a groove such as an existing circuit groove, unevenness of the groove having a large height difference causes a large current difference between a high-current part and a low-current part during electroplating to increase a thickness difference of the plated part between the high-current part and the low-current part. In response to this, the current difference between the high-current part and the low-current part during electroplating is minimized and the difference in plating thickness between the high-current part and the low-current part is minimized. This improves uniform electrodeposition property while suppressing fluctuations, making it possible to form the plated part 3 with high uniformity.

For formation of the plated part 3 only through electroless plating, if a plated part is to be formed by using electroless plating by burying a groove such as an existing circuit groove, a considerably long time is required for an electroless plating processing step as a deposition speed is low in electroless plating. In response to this, the plated part 31 can be formed in such a manner as to extend continuously by filling the non-penetrating holes 4 with plated portions by electroless plating. Thus, time required for the electroless plating processing step can be shortened significantly. Furthermore, unbalance of a thickness is suppressed, making it possible to improve smoothness of the outer surface of the plated part 31 to a greater extent. Additionally, wiring for electric conduction and a facility for electroplating become unnecessary, and the occurrence of a situation where a region for the plated part 31 covering the partial region R becomes larger than necessary can be minimized.

### Plated Molded Article and Method for Manufacturing Plated Molded Article of Second Embodiment

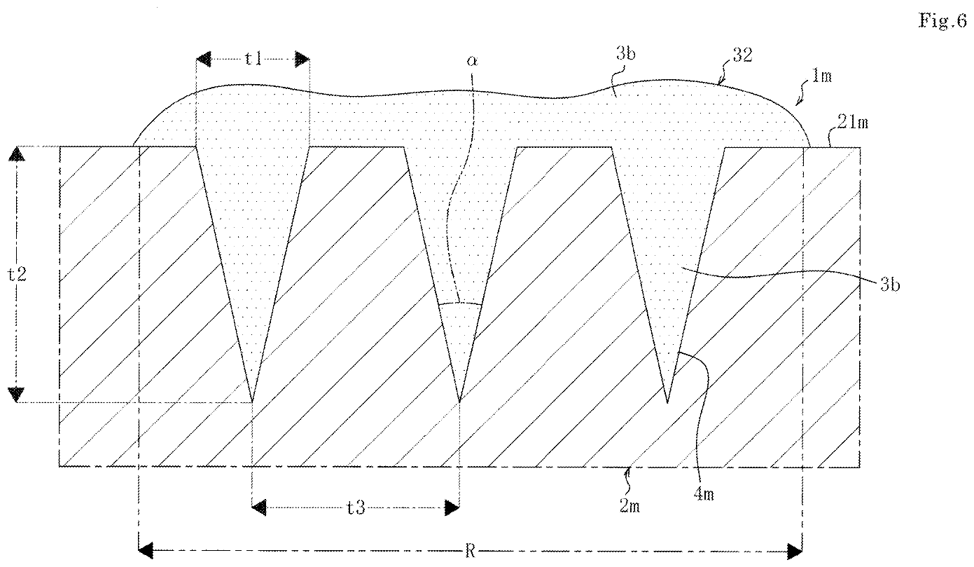

As shown in FIG. 6, in a plated molded article 1m of a second embodiment according to the present invention, a plated part 32 composed of an electroplated part 3b is formed in such a manner as to cover a partial region R in one surface 21m of a rigid base material 2m. In this example, the base material 2m is a base material made of conductive metal, and the partial region R in the one surface 21m of the base material 2m is a region substantially corresponding to the plated part 32 or a region slightly narrower than the plated part 32.

The partial region R in the one surface 21m of the conductive base material 2m is provided with a plurality of non-penetrating holes 4m of substantially corresponding shapes and substantially corresponding sizes that are formed in a scattered pattern in such a manner as to be separated from each other at a substantially averaged hole density. In other words, the partial region R is a region where the non-penetrating holes 4m of substantially corresponding shapes and substantially corresponding sizes are formed in a scattered pattern in such a manner as to be separated from each other at a substantially averaged hole density.

Like in the example shown in FIGS. 2(a) and (b), the non-penetrating holes 4m of this example are arranged in a staggered pattern in a direction in which the partial region R extends, and the non-penetrating holes 4m are formed at respective positions differing from each other in a direction of the width of the partial region R and are formed in the direction in which the partial region R extends. Like in the different example in FIG. 2(c), in a favorable configuration, the non-penetrating holes 4m are arranged in rows and in columns in the direction in which the partial region R extends.

As shown in FIG. 6, the plated part 32 composed of the electroplated part 3b of the plated molded article 1m is formed while being fixedly attached to an inner peripheral surface of each of the non-penetrating holes 4m of the base material 2m and filling each non-penetrating hole 4m. In this example, the non-penetrating hole 4m and a portion of the plated part 32 filling the non-penetrating hole 4m each have a substantially tapered shape with a diameter decreasing gradually toward the back of the non-penetrating hole 4m. The plated part 32 composed of the electroplated part 3b is provided on the one surface 21m of the base material 2m continuously over the partial region R in such a manner as to extend across the non-penetrating holes 4m. In FIG. 6, t1 is a width defined by a maximum width of the non-penetrating hole 4m at the base material surface 21. If the non-penetrating hole 4m is substantially circular in a plan view, for example, t1 is a hole diameter of the non-penetrating hole 4m. Furthermore, t2 is the depth of the non-penetrating hole 4m, and t3 is a pitch between the non-penetrating holes 4m, 4m and is a distance between the center of the non-penetrating hole 4m and the center of the non-penetrating hole 4m.

Like in the case of the plated part 3 or 31 of the first embodiment, from the viewpoint of achieving formation of the plated part 32 composed of the electroplated part 3b in a short time, ensuring of smoothness of an outer surface of the plated part 32, and ensuring of adhesion property of the plated part 32 simultaneously, the height or thickness of the plated part 32 from the one surface 21m of the base material 2m is preferably from 0.5 to 1.36 in terms of a thickness ratio (a ratio expressed as: plating thickness/width t1 of non-penetrating hole), the hole area of the non-penetrating hole 4m is preferably from 3.1×10² to 1256×10² μm², more preferably, from 11.3×10² to 88.2×10² μm², the hole volume of the non-penetrating hole 4m is preferably from 0.9×10³ to 31316×10³ μm³, more preferably, from 15×10³ to 341×10³ μm³, and a mutual spacing ratio between the non-penetrating holes 4m, 4m is preferably from 0.16 to 1.30, more preferably, from 0.28 to 1.27. Here, the mutual spacing ratio between the non-penetrating holes 4m, 4m is defined as: distance between closest positions of non-penetrating holes 4m, 4m/width t1 of non-penetrating hole 4m. From a similar point of view, with the non-penetrating hole 4m formed into a substantially tapered shape or a tapered shape, a taper angle α defined by a line extended from the deepest position of the non-penetrating hole 4m to a periphery of the non-penetrating hole 4m is preferably from 30 to 96 degrees, more preferably, from 30 to 93 degrees. Furthermore, for smoothness of the outer surface of the plated part 32 composed of the electroplated part 3b, a height difference of the outer surface of the plated part 3b determined on a base surface in an intermediate region is preferably equal to or less than 25 μm, more preferably, equal to 20 μm, still more preferably, equal to 15 μm, further preferably, 10 μm. Regarding acquisition of a substantially averaged hole density of the non-penetrating holes 4m, a difference between a maximum distance and a minimum distance of the shortest separation between the non-penetrating holes 4m, 4m is preferably within 50%, and a difference in hole density per 1 mm² in a region where the non-penetrating holes 4m are formed is preferably within 50%.

Moreover, from the viewpoint of forming the plated part 32 by connecting plated portions filling the respective non-penetrating holes 4m in a considerably short time and improving smoothness and adhesion property of the plated part 32 more reliably, the hole area of the non-penetrating hole 4m is preferably from 3.1×10² to 1256×10² μm², more preferably, from 11.3×10² to 88.2×10² μm², and the hole volume of the non-penetrating hole 4m is preferably from 0.9×10³ to 31316×10³ μm³, more preferably, from 15×10³ to 341×10³ μm³. Furthermore, from the viewpoint of preventing overlap between the non-penetrating holes 4m, 4m reliably to ensure favorable deposition property of plating and connecting the plated portions filling the respective non-penetrating holes 4m reliably to provide the plated part 32 continuously, the hole area of the non-penetrating hole 4m is preferably from 3.1×10² to 1256×10² μm², more preferably, from 11.3×10² to 88.2×10² μm², and a mutual spacing ratio between the non-penetrating holes 4m, 4m is preferably from 0.16 to 1.30, more preferably, from 0.28 to 1.27.

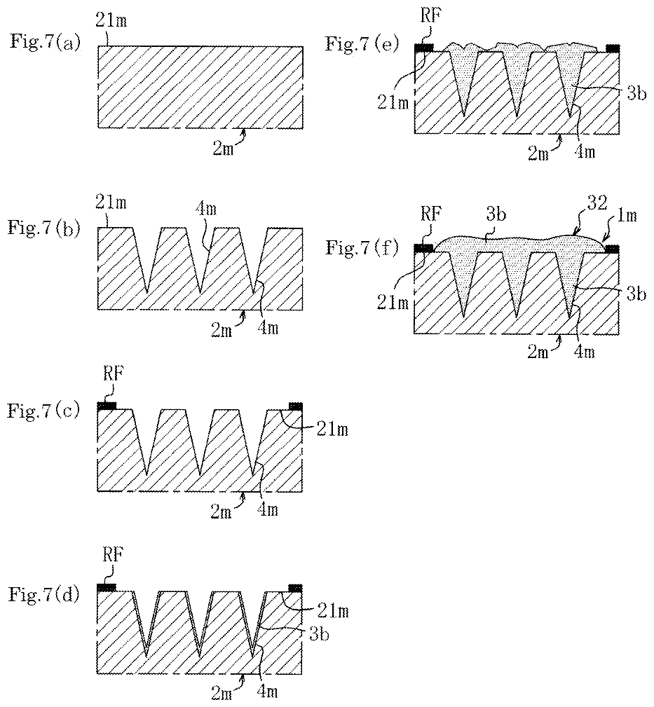

As shown in FIG. 7, for forming the plated part 32 of the plated molded article 1m of the second embodiment, holes are bored by laser processing in the partial region R in the one surface 21m of the conductive base material 2m to form the non-penetrating holes 4m in such a manner that the non-penetrating holes 4m are separated from each other at a substantially averaged hole density (see FIGS. 7(a) and (b)). A laser used in this laser processing is also an appropriately available laser such as a carbon dioxide laser, an ultraviolet laser, a YAG laser, a fiber laser, a semiconductor laser, or a hybrid laser of a fiber laser and a semiconductor laser, for example.

Then, electroplating is performed in the partial region R in the base material 2 provided with the non-penetrating holes 4m. By doing so, the plated part 32 composed of the electroplated part 3b is provided continuously over the partial region R in such a manner as to fill the non-penetrating holes 4m and to extend across the non-penetrating holes 4m, 4m (see FIGS. 7(c) to (f).

In a step of performing electroplating in the partial region R in the base material 2m provided with the non-penetrating holes 4m, a resist film RF is provided in a region where formation of the plated part 32 composed of the electroplated part 3b is unnecessary, and electroplating is performed in an electroplating bath, for example. Then, the electroplated part 3b is deposited and grown sequentially inside the non-penetrating hole 4m and on the base material 21m. By doing so, the non-penetrating holes 4m are each filled with the electroplated part 3b and the electroplated part 3b is provided continuously over the partial region R in the one surface 21m of the base material 2m in such a manner as to extend across the non-penetrating holes 4m, 4m (see FIGS. 7(e) and (f)). For example, the electroplated part 3b is favorably made of copper or a copper alloy, nickel or a nickel alloy, palladium or a palladium alloy, tin or a tin alloy, silver or a silver alloy, gold or a gold alloy, or cobalt or a cobalt alloy.

With the configuration corresponding to that of the first embodiment, the second embodiment achieves effect comparable to the effect achieved by the first embodiment. Furthermore, if electroplating is used for forming a plated part by burying a groove of a size comparable to that of an existing circuit groove, unevenness of the groove having a large height difference causes a large current difference between a high-current part and a low-current part to increase a thickness difference of the plated part between the high-current part and the low-current part. In response to this, by forming the plated part 32 continuously by filling the non-penetrating holes 4m with plated portions through electroplating, the current difference between the high-current part and the low-current part is minimized and the difference in plating thickness between the high-current part and the low-current part is minimized. This improves uniform electrodeposition property while suppressing fluctuations, making it possible to form the plated part 32 with high uniformity.

[Coverage of Invention Disclosed In Present Description]

The invention disclosed in the present description includes not only the aspects described as the invention and the embodiments, but also, within an applicable range, an aspect specified by changing some contents disclosed herein to other contents disclosed in the present description, an aspect specified by adding other contents disclosed in the present description to the contents disclosed herein, and an aspect specified by deleting some contents disclosed herein within a limit allowing fulfillment of partial effects so as to produce a generic concept. The invention disclosed in the present description includes modifications and additions described below.

While the insulating base material 2 according to the above-described first embodiment is an insulating resin base material, an appropriate material is available as the insulating base material according to the present invention within an applicable range. For example, glass, ceramic, etc. are available as the insulating base material 2. While the conductive base material 2m according to the above-described second embodiment is a base material made of conductive metal, an appropriate material is available as the conductive base material according to the present invention within an applicable range.

In the first or second embodiment, the non-penetrating hole 4 or 4m and a portion of the plated part 3, 31, or 32 filling this non-penetrating hole each have a substantially tapered shape with a diameter decreasing gradually toward the back of the non-penetrating hole 4 or 4m. However, the shapes of the non-penetrating hole 4 or 4m and a portion of the plated part 3, 31, or 32 filling this non-penetrating hole may be determined appropriately within a range of the purport of the present invention. For example, a shape such as a substantially circular columnar shape is favorable as it improves adhesion property. Additionally, the non-penetrating hole 4 or 4m can be formed by an appropriate processing method other than laser processing.

While the plated molded article 1 of the first embodiment has been described as a molded interconnect device or a stereoscopic molded interconnect device, the plated molded article of the present invention is not limited to a molded interconnect device but an appropriate molded article is covered within a range of the purport of the present invention. The plated molded article of the present invention can be an appropriate plated molded article with a plated part provided on an insulating base material or a conductive base material.

Regarding electroless plating process and electroplating process performed sequentially or electroless plating process performed alone during manufacture of the plated molded article 1 of the above-described embodiment, or regarding electroplating process performed alone during manufacture of the plated molded article 1m, the substances of the steps of these processes are given as preferred embodiments and it is allowed to perform appropriate process other than these processes.

### Example and Comparable Example

The following describes Examples and Comparative Examples of the plated molded article of the present invention. Tables 1 to 4 show Examples 1 to 25, and Table 5 shows Comparative Examples 1 to 7.

In each of Examples 1 to 25, a surface of an insulating resin base material (material: epoxy resin) was provided with a plurality of non-penetrating holes of substantially corresponding shapes and substantially corresponding sizes that were formed like dots in a scattered pattern in such a manner as to be separated from each other at a substantially averaged hole density. Then, a plated part was provided continuously in such a manner as to fill the non-penetrating holes and to extend across the non-penetrating holes. The non-penetrating holes were formed using laser processing. In the tables, hybrid means a hybrid laser of a fiber laser and a semiconductor layer. In the tables, UV means an ultraviolet laser. A plating solution used for forming the plated part includes solution A: TOPLUCINA 2000 available from OKUNO CHEMICAL INDUSTRIES CO., LTD. and solution B: COPPER GLEAM HS-200 available from ROHM AND HAAS ELECTRONIC MATERIALS K. K.

In each of Examples 1 to 25, a plating thickness used in a thickness ratio of the non-penetrating hole (plating thickness/width t1 of non-penetrating hole) is a thickness corresponding to a height from the surface of the base material, and was acquired by cutting the plated part of a shape like a circuit line after the plating, observing a section under a microscope and measuring heights (thicknesses) from the base material surface randomly at 10 positions, and calculating an average of the heights. In each of Examples 1 to 25, the width t1 of the non-penetrating hole used in the thickness ratio of the non-penetrating hole (plating thickness/width t1 of non-penetrating hole) was acquired by observing the base material surface entirely under a laser microscope after drawing of the non-penetrating hole, measuring the widths of 10 non-penetrating holes randomly from the surface, and calculating an average of the widths. The result obtained by dividing the plating thickness by the width t1 of the non-penetrating hole was acquired as the thickness ratio of the non-penetrating hole.

In each of Examples 1 to 25, a mutual spacing ratio between the non-penetrating holes was acquired by obtaining a mutual spacing between the non-penetrating holes defined as: distance between closest positions of non-penetrating holes/width t1 of non-penetrating hole, and making a calculation as follows: mutual spacing of non-penetrating holes/width t1 of non-penetrating hole.

In each of Examples 1 to 25, the hole area of the non-penetrating hole was acquired by assuming the width t1 of the non-penetrating hole as the diameter of a circle, and making a calculation using a calculation formula of (width t of non-penetrating hole×½)²×3.14.

In each of Examples 1 to 25, for acquisition of the hole volume of the non-penetrating hole, the depth t2 of the non-penetrating hole was first acquired by observing a drawing region entirely under a laser microscope after drawing of the non-penetrating holes, measuring the depths of 10 non-penetrating holes randomly from the region, and calculating an average of the depths. Then, on the assumption that the shape of the non-penetrating hole is a conical shape, the hole volume of the non-penetrating hole was acquired using a calculation formula of (hole area×depth t2 of non-penetrating hole)/3.

In each of Examples 1 to 25, a taper angle of the non-penetrating hole was acquired by assuming the non-penetrating hole as a section of a conical shape, and making a calculation using a calculation formula of tan⁻¹(width t1 of non-penetrating hole/depth t2 of non-penetrating hole).

In each of Examples 1 to 25, a total volume of base material hole filling is the volume of the plated part filling and buried in the non-penetrating holes. A total volume of a plated circuit is the volume of the plated part in its entirety in a state where the plated part fills the non-penetrating holes and is buried in these non-penetrating holes to extend continuously across the non-penetrating holes, and the plated parts like thin lines of an identical unit of 0.5 mm×30 mm are formed on the base material surface, and is a volume as a sum of the total volume of the base material hole filling and the volume of a plating in an upper layer of the base material. The total volume of the plated circuit was acquired by making a calculation as follows: calculated hole volume of non-penetrating hole corresponding to one dot×500 (μm)/(mutual spacing between non-penetrating holes+width t1 of non-penetrating hole)×30000 (μm)/(mutual spacing between non-penetrating holes+width t1 of non-penetrating hole)+(circuit width (500 μm)×circuit length (30000 μm)×average thickness).

In each of Comparative Examples 1 to 7, a recessed groove was formed at a surface of an insulating resin base material (material: epoxy resin), and a plated part was formed in such a manner as to fill the recessed groove. The recessed groove was formed using laser processing. In the tables, hybrid means a hybrid laser of a fiber laser and a semiconductor layer. Like in the above-described case, a plating solution used for forming the plated part was the solution A and the solution B.

In each of Comparative Examples 1 to 7, the depth of the recessed groove was acquired by observing the surface of the resin base material entirely under a laser microscope after drawing of the recessed grooves, measuring the depths of the recessed grooves at 10 positions randomly from the surface, and calculating an average of the depths.

In each of Comparative Examples 1 to 7, a plating thickness was acquired by cutting the plated part of a shape like a circuit line after plating, measuring heights (thicknesses) at a section from the base material surface randomly at 10 positions under a microscope, and calculating an average of the heights.

In each of Comparative Examples 1 to 7, a total volume of base material hole filling is the volume of the plated part filling the recessed groove at the base material in such a manner as to be buried in the recessed groove. A total volume of a plated circuit is the volume of the plated part in its entirety in a state where the plated parts like thin lines of an identical unit of 0.5 mm×30 mm are formed on the base material in such a manner as to fill the recessed groove at the base material, and is a volume as a sum of the total volume of the base material hole filling and the volume of a plating in an upper layer of the base material. The total volume of the plated circuit was acquired by making a calculation as follows: (depth of recessed groove×width of recessed groove×length of recessed groove (30000 μm))+(circuit width (500 μm)×circuit length (30000 μm)×plating thickness).

Each of Examples and each of Comparative Examples were rated in terms of smoothness, adhesion property, deposition property, uniform electrodeposition property, and productivity (plating duration expressed in units of time). Table 1 to Table 5 show ratings on the basis of seven scales that include××meaning very bad, ×meaning bad, Δmeaning slightly inferior, ◯ meaning good, ◯◯ meaning better, ⊚ meaning still better, and ⊚⊚ meaning very good.

For rating of the smoothness, a step height on the outermost surface of the plated part was measured, and step heights from 0 μm to 40 μm or more were rated on the basis of the seven scales. A step height of 0 μm with ⊚⊚ corresponds to a rating of very good, and a step height of 40 μm or more with ×× corresponds to a rating of very bad.

For rating of the adhesion property, a plated part of a shape like a circuit line of 5 mm×60 mm was formed on a base material, an adhesion force was measured using a tension testing machine, and adhesion forces from 0 N/cm to 40 N/cm or more were rated on the basis of the seven scales. An adhesion force of 0 N/cm with ×× corresponds to a rating of very bad, and an adhesion force of 40 N/cm or more with ⊚⊚ corresponds to a rating of very good.

For rating of the deposition property, a duration until finish of plating coating was rated on the basis of the seven scales. A case where the plated part was coated in a duration of less than 5 minutes corresponds to a rating of very good and is given ⊚⊚, a case where the plated part was not coated even for a duration of 51 minutes or more corresponds to a rating of very bad and is given ××. A duration from 5 to 10 minutes was rated as ⊚, a duration from 11 to 20 minutes was rated as ◯◯, a duration from 21 to 30 minutes was rated as ◯, a duration from 31 to 40 minutes was rated as A, and a duration from 41 to 50 minutes was rated as ×.

For rating of the uniform electrodeposition property, a value calculated in terms of a plating thickness ratio (minimum/maximum×100=%) between an extreme tip and a position in the vicinity of a contact point of each test sample having thin lines of an identical unit of 0.5 mm×30 mm was rated on the basis of the seven scales. Rating was given separately while a value of equal to or greater than 86% was rated as very good and given ⊚⊚, and a value of equal to or less than 10% was rated as very bad and given ××. A value from 71 to 85% was rated as ⊚, a value from 56 to 70% was rated as ◯◯, a value from 41 to 55% was rated as ◯, a value from 26 to 41% was rated as A, and a vale rom 11 to 25% was rated as ×.

As clearly understood from Examples 1 to 25 and Comparative Examples 1 to 7, each of Examples 1 to 25 was found to achieve formation of the plated part with considerably excellent smoothness compared to Comparative Examples 1 to 7 and also achieves excellence in terms of adhesion property. It is also shown clearly that each of Examples 1 to 25 tends to allow formation of plated parts as thin lines of an identical unit in a shorter time than Comparative Examples 1 to 7.

TABLE 1

| | Example 1 | Example 2 | Example 3 | Example 4 | Example 5 | Example 6 | Example 7 |
|---|---|---|---|---|---|---|---|
| Used laser | hybrid | hybrid | hybrid | hybrid | hybrid | hybrid | hybrid |
| Shape of recess | dot | dot | dot | dot | dot | dot | dot |
| Pitch between non-penetrating | 150 | 150 | 150 | 150 | 150 | 150 | 200 |
| holes(t3: μm) | | | | | | | |
| Type of plating solution | solution A | solution B | solution A | solution B | solution A | solution B | solution A |
| Mutual spacing ratio between | 0.46 | 0.46 | 0.46 | 0.46 | 0.42 | 0.42 | 0.94 |
| non-penetrating holes | | | | | | | |
| Hole area of non-penetrating | 83.3 | 83.3 | 83.3 | 83.3 | 88.2 | 88.2 | 83.3 |
| hole (μm² × 10²) | | | | | | | |
| Hole volume of non-penetrating | 136 | 136 | 136 | 136 | 341 | 341 | 136 |
| hole (μm³ × 10³) | | | | | | | |
| Total volume of base material | 91 | 91 | 91 | 91 | 227 | 227 | 51 |
| hole filling (μm³ × 10⁶) | | | | | | | |
| Total volume of plated circuit | 945 | 1066 | 1516 | 1666 | 1802 | 1877 | 1581 |
| (μm³ × 10⁶) | | | | | | | |
| Thickness ratio of non-penetrating | 0.61 | 0.63 | 0.92 | 1.02 | 0.99 | 1.04 | 0.99 |
| hole (plating thickness/t1) | | | | | | | |
| Angle value of taper angle of | 93 | 93 | 93 | 93 | 49 | 49 | 93 |
| non-penetrating hole (α) | | | | | | | |
| Smoothness | ⊚ | ⊚ | ⊚⊚ | ⊚ | ⊚⊚ | ◯ | ⊚⊚ |
| Adhesion property | ◯◯ | ◯◯ | ◯◯ | ⊚ | ◯◯ | ⊚ | ◯◯ |
| Deposition property | ⊚ | ⊚ | ⊚ | ⊚ | ⊚ | ⊚ | ⊚ |
| Uniform electrodeposition property | Δ | ⊚ | Δ | ⊚ | Δ | ⊚ | ◯ |
| Productivity (plating time: h) | 1.8 | 1.8 | 2.7 | 2.9 | 2.9 | 3.1 | 2.9 |

TABLE 2

| | Example 8 | Example 9 | Example 10 | Example 11 | Example 12 | Example 13 | Example 14 |
|---|---|---|---|---|---|---|---|
| Used laser | hybrid | hybrid | hybrid | hybrid | hybrid | hybrid | hybrid |
| Shape of recess | dot | dot | dot | dot | dot | dot | dot |
| Pitch between non-penetrating | 200 | 200 | 200 | 200 | 200 | 200 | 200 |
| holes(t3: μm) | | | | | | | |
| Type of plating solution | solution B | solution A | solution B | solution A | solution B | solution A | solution B |
| Mutual spacing ratio between | 0.94 | 0.94 | 0.94 | 0.94 | 0.94 | 0.94 | 0.94 |
| non-penetrating holes | | | | | | | |
| Hole area of non-penetrating | 83.3 | 83.3 | 83.3 | 83.3 | 83.3 | 83.3 | 83.3 |
| hole (μm² × 10²) | | | | | | | |
| Hale volume of non-penetrating | 136 | 169 | 169 | 169 | 169 | 169 | 169 |
| hole (μm³ × 10³) | | | | | | | |
| Total volume of base material | 51 | 64 | 64 | 64 | 64 | 64 | 64 |
| hole filling (μm³ × 10⁶) | | | | | | | |
| Total volume of plated circuit | 1716 | 1039 | 1084 | 1264 | 844 | 1789 | 1804 |
| (μm³ × 10⁶) | | | | | | | |
| Thickness ratio of non-penetrating | 1.08 | 0.63 | 0.66 | 0.78 | 0.50 | 1.12 | 1.13 |
| hole (plating thickness/t1) | | | | | | | |
| Angle value of taper angle of | 93 | 80 | 80 | 80 | 80 | 80 | 80 |
| non-penetrating hole (α) | | | | | | | |
| Smoothness | ⊚⊚ | ⊚ | ◯◯ | ⊚ | ◯ | ⊚ | ⊚ |
| Adhesion property | ⊚ | ⊚ | ⊚ | ◯◯ | ◯◯ | ◯◯ | ⊚ |
| Deposition property | ◯ | ◯ | ◯ | ◯ | ◯ | ◯ | ◯ |
| Uniform electrodeposition property | ⊚ | ◯ | ⊚ | Δ | ⊚ | Δ | ⊚ |
| Productivity (plating time: h) | 3.1 | 1.8 | 1.9 | 2.2 | 1.5 | 3.2 | 3.3 |

TABLE 3

| | Example 15 | Example 16 | Example 17 | Example 18 | Example 19 | Example 20 |
|---|---|---|---|---|---|---|
| Used laser | UV | UV | UV | UV | UV | UV |
| Shape of recess | dot | dot | dot | dot | dot | dot |
| Pitch between non-penetrating | 50 | 50 | 65 | 65 | 65 | 65 |
| holes(t3: μm) | | | | | | |
| Type of plating solution | solution A | solution B | solution A | solution B | solution A | solution B |
| Mutual spacing ratio between | 0.28 | 0.28 | 0.63 | 0.63 | 0.71 | 0.71 |
| non-penetrating holes | | | | | | |
| Hole area of non-penetrating | 11.9 | 11.9 | 12.6 | 12.6 | 11.3 | 11.3 |
| hole (μm² × 10²) | | | | | | |
| Hole volume of non-penetrating | 29 | 29 | 23 | 23 | 15 | 15 |
| hole (μm³ × 10³) | | | | | | |
| Total volume of base material | 174 | 174 | 80 | 80 | 54 | 54 |
| hole filling (μm³ × 10⁶) | | | | | | |
| Total volume of plated circuit | 849 | 849 | 770 | 770 | 654 | 654 |
| (μm³ × 10⁶) | | | | | | |
| Thickness ratio of non-penetrating | 1.15 | 1.15 | 1.15 | 1.15 | 1.05 | 1.05 |
| hole (plating thickness/t1) | | | | | | |
| Angle value of taper angle of | 30 | 30 | 41 | 41 | 51 | 51 |
| non-penetrating hole (α) | | | | | | |
| Smoothness | ⊚ | ◯◯ | ⊚⊚ | ⊚⊚ | ⊚⊚ | ⊚⊚ |
| Adhesion property | ⊚ | ⊚ | ◯◯ | ⊚ | ◯◯ | ⊚ |
| Deposition property | ⊚ | ⊚ | ⊚ | ⊚ | ⊚ | ⊚ |
| Uniform electrodeposition property | Δ | ⊚ | Δ | ⊚ | Δ | ⊚ |
| Productivity (plating time: h) | 1.3 | 1.3 | 1.3 | 1.3 | 1.1 | 1.1 |

TABLE 4

| | Example 21 | Example 22 | Example 23 | Example 24 | Example 25 |
|---|---|---|---|---|---|
| Used laser | UV | UV | UV | UV | UV |
| Shape of recess | dot | dot | dot | dot | dot |
| Pitch between non-penetrating | 65 | 65 | 80 | 100 | 100 |
| holes(t3: μm) | | | | | |
| Type of plating solution | solution A | solution B | solution B | solution A | solution B |
| Mutual spacing ratio between non- | 0.63 | 0.63 | 0.82 | 1.27 | 1.27 |
| penetrating holes | | | | | |
| Hole area of non-penetrating hole | 12.6 | 12.6 | 15.2 | 15.2 | 15.2 |
| (μm² × 10²) | | | | | |
| Hole volume of non-penetrating hole | 26 | 26 | 25 | 31 | 31 |
| (μm³ × 10³) | | | | | |
| Total volume of base material hole | 92 | 92 | 58 | 47 | 47 |
| filling (μm³ × 10⁶) | | | | | |
| Total volume of plated circuit | 842 | 842 | 823 | 947 | 947 |
| (μm³ × 10⁶) | | | | | |
| Thickness ratio of non-penetrating | 1.25 | 1.25 | 1.16 | 1.36 | 1.36 |
| hole (plating thickness/t1) | | | | | |
| Angle value of taper angle of non- | 36 | 36 | 48 | 39 | 39 |
| penetrating hole (α) | | | | | |
| Smoothness | ⊚⊚ | ⊚ | ⊚⊚ | ⊚⊚ | ⊚⊚ |
| Adhesion property | ⊚ | ⊚ | ⊚ | ⊚ | ⊚ |
| Deposition property | ⊚ | ⊚ | ◯ | ◯ | ◯ |
| Uniform electrodeposition property | Δ | ⊚ | ⊚ | Δ | ⊚ |
| Productivity (plating time: h) | 1.4 | 1.4 | 1.4 | 1.7 | 1.7 |

TABLE 5

| | Comparative | Comparative | Comparative | Comparative | Comparative | Comparative | Comparative |
|---|---|---|---|---|---|---|---|
| | example 1 | example 2 | example 3 | example 4 | example 5 | example 6 | example 7 |
| Used laser | hybrid | hybrid | hybrid | hybrid | hybrid | hybrid | hybrid |
| Shape of recess | recessed | recessed | recessed | recessed | recessed | recessed | recessed |
| | groove | groove | groove | groove | groove | groove | groove |
| Type of solution | solution A | solution B | solution A | solution B | solution A | solution B | solution A |
| Depth of recessed groove (μm) | 58 | 58 | 92 | 92 | 92 | 92 | 170 |
| Plating thickness (μm) | 40 | 40 | 65 | 67 | 92 | 98 | 72 |
| Total volume of base material | 870 | 870 | 1380 | 1380 | 1380 | 1380 | 2550 |
| hole filling (μm³ × 10⁶) | | | | | | | |
| Total volume of a plated circuit | 1470 | 1470 | 2355 | 2385 | 2760 | 2850 | 3630 |
| (μm³ × 10⁶) | | | | | | | |
| Smoothness | XX | XX | XX | XX | XX | XX | XX |
| Adhesion property | Δ | Δ | Δ | Δ | Δ | Δ | Δ |
| Deposition property | ⊚ | ⊚ | ⊚ | ⊚ | ⊚ | ⊚ | ⊚ |
| Uniform electrodeposition property | Δ | ⊚ | Δ | ⊚ | X | ⊚ | X |
| Productivity (plating time: h) | 2.8 | 2.8 | 4.4 | 4.5 | 5.2 | 5.3 | 6.8 |

### INDUSTRIAL APPLICABILITY

The present invention is available for a plated molded article such as a stereoscopic molded interconnect device, for example.

### REFERENCE SIGNS LIST

1, 1m . . . Plated molded article
2, 2m . . . Base material
21, 21m . . . Surface
3, 31, 32 . . . Plated part
3a . . . Electroless plated part
3b . . . Electroplated part
4, 4m . . . Non-penetrating hole
R . . . Partial region
t1 . . . Width of non-penetrating hole
t2 . . . Depth of non-penetrating hole
t3 . . . Pitch between non-penetrating holes
a . . . Taper angle of non-penetrating hole having tapered shape
C . . . Catalyst
RF . . . Resist film
100 . . . Resin base material
101 . . . Surface
102 . . . Groove
103 . . . Plated part
103a . . . Electroless plated part
103b . . . Electroplated part

1-9. (canceled)

10. A plated molded article wherein
a partial region in a surface of a base material is provided with a plurality of non-penetrating holes of substantially corresponding shapes and substantially corresponding sizes that are formed in a scattered pattern in such a manner as to be separated from each other at a substantially averaged hole density, and
a plated part is formed while filling the non-penetrating holes and is provided continuously over the partial region in such a manner as to extend across the non-penetrating holes.

11. The plated molded article according to claim 10, wherein
the non-penetrating holes and portions of the plated part filling the non-penetrating holes each have a substantially tapered shape with a diameter decreasing gradually toward the back of the non-penetrating hole.

12. The plated molded article according to claim 10, wherein
the non-penetrating holes have a hole area from 3.1×10² to 1256×10² μm² and the non-penetrating holes have a hole volume of 0.9×10³ to 31316×10³ μm³.

13. The plated molded article according to claim 11, wherein
the non-penetrating holes have a hole area from 3.1×10² to 1256×10² μm² and the non-penetrating holes have a hole volume of 0.9×10³ to 31316×10³ μm³.

14. The plated molded article according to claim 10, wherein
the non-penetrating holes have a hole area from 3.1×10² to 1256×10² μm² and a mutual spacing ratio between the non-penetrating holes is from 0.16 to 1.30.

15. The plated molded article according to claim 11, wherein
the non-penetrating holes have a hole area from 3.1×10² to 1256×10² μm² and a mutual spacing ratio between the non-penetrating holes is from 0.16 to 1.30.

16. The plated molded article according to claim 10, wherein
the non-penetrating holes are arranged in a staggered pattern or in rows and in columns in a direction in which the partial region extends.

17. The plated molded article according to claim 11, wherein
the non-penetrating holes are arranged in a staggered pattern or in rows and in columns in a direction in which the partial region extends.

18. The plated molded article according to claim 10, wherein
the base material is an insulating resin base material and the partial region in the surface of the base material is a region substantially corresponding to a conductor,
the non-penetrating holes are formed at respective positions differing from each other in a direction of the width of the conductor and are formed in a direction in which the conductor extends, and
the conductor is formed using the plated part to form a molded interconnect device.

19. The plated molded article according to claim 11, wherein
the base material is an insulating resin base material and the partial region in the surface of the base material is a region substantially corresponding to a conductor,
the non-penetrating holes are formed at respective positions differing from each other in a direction of the width of the conductor and are formed in a direction in which the conductor extends, and
the conductor is formed using the plated part to form a molded interconnect device.

20. The plated molded article according to claim 12, wherein
the base material is an insulating resin base material and the partial region in the surface of the base material is a region substantially corresponding to a conductor,
the non-penetrating holes are formed at respective positions differing from each other in a direction of the width of the conductor and are formed in a direction in which the conductor extends, and
the conductor is formed using the plated part to form a molded interconnect device.

21. The plated molded article according to claim 14, wherein
the base material is an insulating resin base material and the partial region in the surface of the base material is a region substantially corresponding to a conductor,
the non-penetrating holes are formed at respective positions differing from each other in a direction of the width of the conductor and are formed in a direction in which the conductor extends, and
the conductor is formed using the plated part to form a molded interconnect device.

22. The plated molded article according to claim 16, wherein
the base material is an insulating resin base material and the partial region in the surface of the base material is a region substantially corresponding to a conductor,
the non-penetrating holes are formed at respective positions differing from each other in a direction of the width of the conductor and are formed in a direction in which the conductor extends, and
the conductor is formed using the plated part to form a molded interconnect device.

23. A method for manufacturing the plated molded article according to claim 10, comprising:
a first step of boring holes in a partial region in a surface of an insulating base material by laser processing to form a plurality of non-penetrating holes in such a manner that the non-penetrating holes are separated from each other at a substantially averaged hole density; and
a second step of performing electroless plating in the partial region in the base material provided with the non-penetrating holes to provide a plated part continuously over the partial region in such a manner that the plated part fills the non-penetrating holes and extends across the non-penetrating holes.

24. A method for manufacturing the plated molded article according to claim 11, comprising:
a first step of boring holes in a partial region in a surface of an insulating base material by laser processing to form a plurality of non-penetrating holes in such a manner that the non-penetrating holes are separated from each other at a substantially averaged hole density; and
a second step of performing electroless plating in the partial region in the base material provided with the non-penetrating holes to provide a plated part continuously over the partial region in such a manner that the plated part fills the non-penetrating holes and extends across the non-penetrating holes.

25. A method for manufacturing the plated molded article according to claim 18, comprising:
a first step of boring holes in a partial region in a surface of an insulating base material by laser processing to form a plurality of non-penetrating holes in such a manner that the non-penetrating holes are separated from each other at a substantially averaged hole density; and
a second step of performing electroless plating in the partial region in the base material provided with the non-penetrating holes to provide a plated part continuously over the partial region in such a manner that the plated part fills the non-penetrating holes and extends across the non-penetrating holes.

26. A method for manufacturing the plated molded article according to claim 10, comprising:
a first step of boring holes in a partial region in a surface of an insulating base material by laser processing to form a plurality of non-penetrating holes in such a manner that the non-penetrating holes are separated from each other at a substantially averaged hole density; and
a second step of performing electroless plating and electroplating sequentially in the partial region in the base material provided with the non-penetrating holes to provide a plated part continuously over the partial region in such a manner that the plated part fills the non-penetrating holes and extends across the non-penetrating holes.

27. A method for manufacturing the plated molded article according to claim 11, comprising:
a first step of boring holes in a partial region in a surface of an insulating base material by laser processing to form a plurality of non-penetrating holes in such a manner that the non-penetrating holes are separated from each other at a substantially averaged hole density; and
a second step of performing electroless plating and electroplating sequentially in the partial region in the base material provided with the non-penetrating holes to provide a plated part continuously over the partial region in such a manner that the plated part fills the non-penetrating holes and extends across the non-penetrating holes.

28. A method for manufacturing the plated molded article according to claim 18, comprising:
a first step of boring holes in a partial region in a surface of an insulating base material by laser processing to form a plurality of non-penetrating holes in such a manner that the non-penetrating holes are separated from each other at a substantially averaged hole density; and
a second step of performing electroless plating and electroplating sequentially in the partial region in the base material provided with the non-penetrating holes to provide a plated part continuously over the partial region in such a manner that the plated part fills the non-penetrating holes and extends across the non-penetrating holes.

29. A method for manufacturing the plated molded article according to claim 10, comprising:
a first step of boring holes in a partial region in a surface of a conductive base material by laser processing to form a plurality of non-penetrating holes in such a manner that the non-penetrating holes are separated from each other at a substantially averaged hole density; and
a second step of performing electroplating in the partial region in the base material provided with the non-penetrating holes to provide a plated part continuously over the partial region in such a manner that the plated part fills the non-penetrating holes and extends across the non-penetrating holes.

30. A method for manufacturing the plated molded article according to claim 11, comprising:
a first step of boring holes in a partial region in a surface of a conductive base material by laser processing to form a plurality of non-penetrating holes in such a manner that the non-penetrating holes are separated from each other at a substantially averaged hole density; and
a second step of performing electroplating in the partial region in the base material provided with the non-penetrating holes to provide a plated part continuously over the partial region in such a manner that the plated part fills the non-penetrating holes and extends across the non-penetrating holes.
